(19) United States
(12) Patent Application Publication
(10) Pub. No.: US 2005/0156681 A1
(43) Pub. Date: Jul. 21, 2005

(54) Voltage controlled oscillator

(76) Inventors: Koji Takinami, Osaka (JP); Takayuki Tsukizawa, Neyagawa (JP); Hisashi Adachi, Mino (JP); Atsushi Ohara, Otsu (JP)

Correspondence Address: WENDEROTH, LIND & PONACK, L.L.P., 2033 K STREET N. W., SUITE 800, WASHINGTON, DC, 20006-1021, US

(21) Appl. No.: 11/025,154

(22) Filed: Dec. 30, 2004

(30) Foreign Application Priority Data
Jan. 20, 2004 (JP) 2004-011936

(51) Int. Cl. H03K 3/26

(52) U.S. Cl. 331/117 R

(57) ABSTRACT

The present invention provides a voltage controlled oscillator for changing an oscillating frequency in accordance an input control voltage, including a parallel resonant circuit, a negative resistance circuit connected in parallel to the parallel resonant circuit, a first capacitor connected in parallel to the negative resistance circuit, a first current source connected between one terminal of the first capacitor and the negative resistance circuit, and a second current source connected between the other terminal of the first capacitor and the negative resistance circuit. The capacitance value of the first capacitor is set to a value that suppresses a signal with a frequency twice the oscillating frequency at both the terminals of the first capacitor. Each of the first and the second current sources is constituted by a bipolar transistor.

### BACKGROUND OF THE INVENTION

1. Field of the Invention

The present invention relates to a voltage controlled oscillator used in wireless communication equipment and PLL circuits. More specifically, the present invention relates to a voltage controlled oscillator in which phase noise can be suppressed.

2. Description of the Background Art

Voltage controlled oscillators are widely used as means for generating a local oscillating signal of wireless communication equipment. FIG. 19 is a circuit diagram showing the configuration of a conventional voltage controlled oscillator 900. In FIG. 19, the voltage controlled oscillator includes a power terminal 910, inductors 911 and 912, variable capacitive elements 913 and 914, oscillating transistors 915 and 916, a frequency control terminal 917, and a current source transistor 930. In FIG. 19, a bias circuit and the like are omitted.

In FIG. 19, the inductors 911 and 912 and the variable capacitive elements 913 and 914 constitute a parallel resonant circuit. The capacitance value of the variable capacitive element is determined by a potential difference between its both ends, so that the capacitance value of the variable capacitive elements 913 and 914 is controlled by controlling the control voltage applied to the frequency control terminal 917.

The voltage controlled oscillator 900 oscillates in the vicinity of the resonance frequency of the parallel resonant circuit. Therefore, the oscillating frequency of the voltage controlled oscillator 900 can be set to a desired frequency by controlling the control voltage. The oscillating transistors 915 and 916 generate a negative resistance and cancel the loss due to a parasitic resistance component of the resonant circuit so as to satisfy the oscillating conditions.

FIG. 20A is a schematic diagram showing the temporal change of the voltages at both terminals O1 and O2 of the resonant circuit in the conventional voltage controlled oscillator 900 shown in FIG. 19. In FIG. 20A, the solid line schematically indicates the temporal change of the voltage at the terminal O1, and the dotted line schematically indicates the temporal change of the voltage at the terminal O2. As shown in FIG. 20A, the temporal change of the voltage at each of the terminals O1 and O2 of the resonant circuit forms a sine wave.

FIG. 20B is a schematic diagram showing the temporal change of the voltage at the source terminal P0 of the oscillating transistors 915 and 916 in the conventional voltage controlled oscillator 900 shown in FIG. 19. The fundamental wave in the drain terminal of the oscillating transistor 915 and the fundamental wave in the drain terminal of the oscillating transistor 916 have an equal amplitude and opposite phases. Therefore, at the source terminal P0, the fundamental wave and odd-numbered harmonics cancel each other and only even-numbered harmonics are synthesized. Of the even-numbered harmonics, the second harmonic has the largest power, so that at the source terminal P0, the voltage changes at a frequency of 2 fo, which is twice the oscillating frequency, where fo is the oscillating frequency, as shown in FIG. 20B.

It is known that in general, 1/f noise that is generated in the oscillating transistors 915 and 916 and the current source transistor 930 is converted to a frequency in the vicinity of the oscillating frequency by interaction with the voltage fluctuation due to the frequency 2fo at the source terminal P0. Therefore, the 1/f noise converted to a frequency in the vicinity of the oscillating frequency is superimposed on oscillating signals and becomes phase noise.

FIG. 21 is a diagram showing the phase noise characteristic of the conventional voltage controlled oscillator 900 shown in FIG. 19. In FIG. 21, the horizontal axis shows the frequency offset from the oscillating frequency and the vertical axis shows the magnitude of the phase noise.

As shown in FIG. 21, the phase noise characteristics can be divided into two regions, that is, a region A showing a slope of 9 dB/Oct and a region B showing a slope of 6 dB/Oct. The region A is from 0 Hz to about 50 kHz, and the region B is from about 50 kHz and above. The phase noise in the region B is mainly due to thermal noise.

The phase noise in the region A is caused by the 1/f noise generated in the oscillating transistors 915 and 916 and the current source transistor 930 being converted to a frequency in the vicinity of the oscillating frequency and then superimposed on oscillating signals. The transistor used for the oscillating transistor or the current source transistor is generally a field-effect transistor. The field-effect transistors have large 1/f noise. Therefore, in the conventional voltage control oscillators, occurrence of phase noise in the region A causes a large problem.

As a method to solve this problem, a voltage controlled oscillator disclosed in “CMOS Differential LC Oscillator with Suppressed Up-Converted Flicker Noise” written by Aly Ismail, Asad A. Abidi, 2003 IEEE International Solid-State Circuits Conference, pp. 98-99 (non-patent document 1) has been proposed. FIG. 22 is a circuit diagram showing the configuration of a conventional voltage controlled oscillator 990 as disclosed in this non-patent document 1.

In FIG. 22, the voltage controlled oscillator 990 includes a power terminal 910, inductors 911 and 912, variable capacitive elements 913 and 914, oscillating transistors 915 and 916, a frequency control terminal 917, inductors 918 and 919, a coupling capacitor 920, resistors 921 and 922, a switch 923, and a bias capacitor 924. In FIG. 22, the same portions as in FIG. 19 bear the same reference numerals.

In FIG. 22, the current source transistor 930 in the conventional voltage controlled oscillator 900 shown in FIG. 19 is replaced by a circuit made up of the resistors 921 and 922 and the switch 923. Variations in the resistance value due to variations in the production of the resistors 921 and 922 are adjusted by adjusting the on/off of the switch 923, so that the current value in the voltage controlled oscillator 990 can be set to a desired value. Thus, by replacing the current source transistor by the circuit made up of the resistors 921 and 922 and the switch 923, the 1/f noise generated in the current source transistor 930 can be suppressed. The bias capacitor 924 is provided to remove noise generated in the resistors 921 and 922.

The circuit made up of the coupling capacitor 920 and the inductors 918 and 919 serves to suppress the influence of the 1/f noise generated in the oscillating transistors 915 and 916. The inductors 918 and 919 have a sufficiently large impedance with respect to the oscillating frequency fo. The coupling capacitor 920 has a capacitance value that provides a high impedance with respect to the 1/f noise in the range that satisfies the oscillating conditions. With such impedance and capacitance value, the temporal change of the voltage shown in FIGS. 23B and 23C, which will be described later, can be obtained.

FIG. 23A is a schematic diagram showing the temporal change of the voltages of at both the terminals O1 and O2 of the resonant circuit in the conventional voltage controlled oscillator 990 shown in FIG. 22. In FIG. 23A, the solid line schematically indicates the temporal change of the voltage at the terminal O1, and the dotted line schematically indicates the temporal change of the voltage at the terminal O2. As shown in FIG. 23A, the temporal change of the voltage at each of the terminals O1 and O2 of the resonant circuit forms a sine wave.

FIG. 23B is a schematic diagram showing the temporal change of the voltage at the source terminal P1 of the oscillating transistor 915 in the conventional voltage controlled oscillator 990 shown in FIG. 22. FIG. 23C is a schematic diagram showing the temporal change of the voltage at the source terminal P2 of the oscillating transistor 916 in the conventional voltage controlled oscillator 990 shown in FIG. 22.

In the circuit of FIG. 22, the inductors 918 and 919 have a sufficiently large impedance with respect to the oscillating frequency fo. In this case, when an appropriate value (a value that provides a high impedance with respect to the 1/f noise in the range that satisfies the oscillating conditions) is selected as the capacitance value of the coupling capacitor 920, in the terminals P1 and P2, the 2 fo component can be suppressed, as shown in FIGS. 23B and 23C.

By suppressing the 2 fo component, conversion of the 1/f noise to a frequency in the vicinity of the oscillating frequency due to the interaction between the 1/f noise and the 2 fo component can be reduced, so that the phase noise in the vicinity of the oscillating frequency can be suppressed.

FIG. 24 is a diagram showing the phase noise of the voltage controlled oscillator 990 shown in FIG. 22. As shown in FIG. 24, in the voltage controlled oscillator 990 shown in FIG. 22, the phase noise in the vicinity of the oscillating frequency can be suppressed. For example, the non-patent document 1 describes that the phase noise in the region A is reduced by about 20 dB.

However, in the above configuration, two inductors having a large impedance (e.g., 23 nH in the non-patent document 1) with respect to the oscillating frequency are required. These inductors can be realized in a semiconductor integrated circuit by using spiral inductors, which occupy a large area. Therefore, the chip size of the voltage controlled oscillator is increased, resulting in an increase in the cost.

Furthermore, in the conventional configuration, a resistor is used in place of a current source transistor, so that, for example, when a power voltage is changed, for example, upon operating a transmitting circuit, the current value swings and the oscillating frequency is fluctuated.

### SUMMARY OF THE INVENTION

Therefore, an object of the present invention is to provide a voltage controlled oscillator that has a low cost and has reduced fluctuations in the oscillating frequency.

The present invention has the following features to attain the object mentioned above. A first aspect of the present invention is directed to a voltage controlled oscillator for changing an oscillating frequency in accordance an input control voltage, including a parallel resonant circuit, a negative resistance circuit connected in parallel to the parallel resonant circuit, a first capacitor connected in parallel to the negative resistance circuit, a first current source connected between one terminal of the first capacitor and the negative resistance circuit, and a second current source connected between the other terminal of the first capacitor and the negative resistance circuit. The capacitance value of the first capacitor is a value that suppresses a signal with a frequency twice the oscillating frequency at both the terminals of the first capacitor. Each of the first and the second current sources is constituted by a bipolar transistor.

Thus, a signal with a frequency twice the oscillating frequency can be suppressed, so that the 1/f noise is prevented from being converted to a frequency in the vicinity of the oscillating frequency by the interaction between the second harmonic and the 1/f noise. Thus, the phase noise can be suppressed. Furthermore, the impedance as seen from both the terminals of the first capacitor to the ground is high, using the current sources, so that the circuit can be smaller than a conventional example using an inductor, which can increase the numbers of ICs that can be configured. Thus, low-cost voltage controlled oscillators can be provided. Moreover, the current source is constituted by a bipolar transistor, so that the current value can be stabilized, compared with the conventional technique in which the current source is constituted by a resistor and thus a voltage controlled oscillator having reduced fluctuations of the oscillating frequency can be provided.

For example, the negative resistance circuit includes a first oscillating transistor constituted by an field-effect transistor, a second oscillating transistor constituted by an field-effect transistor, and the parallel resonant circuit is connected between the drains of the first and the second oscillating transistors. The first capacitor is connected between the sources of the first and the second oscillating transistors. The gate of the first oscillating transistor is connected to the drain of the second oscillating transistor. The gate of the second oscillating transistor is connected to the drain of the first oscillating transistor. The collector of the bipolar transistor as the first current source is connected between the first capacitor and the source of the first oscillating transistor. The collector of the bipolar transistor as the second current source is connected between the first capacitor and the source of the second oscillating transistor.

Preferably, the voltage controlled oscillator further includes a first impedance element connected between the collector of the bipolar transistor as the first current source and the first capacitor, and a second impedance element connected between the collector of the bipolar transistor as the second current source and the first capacitor. The first and the second impedance elements have an impedance that suppresses a signal with a frequency twice the oscillating frequency at both the terminals of the first capacitor.

Thus, even if the oscillating frequency is high, the 1/f noise is prevented from being converted to a frequency in the vicinity of the oscillating frequency by the interaction between the second harmonic and the 1/f noise. Thus, a voltage controlled oscillator in which the phase noise can be suppressed can be provided.

For example, the first and the second impedance elements are inductors.

Furthermore, for example, the first and the second impedance elements are a LC parallel resonant circuit including an inductor and a capacitor, and a resonant frequency of the LC parallel resonant circuit is a frequency twice the oscillating frequency.

Thus, the size of the inductor can be further reduced.

Preferably, furthermore, the voltage controlled oscillator further includes a first impedance element connected between the emitter of the bipolar transistor as the first current source and the ground, and a second impedance element connected between the emitter of the bipolar transistor as the second current source and the ground. The first and the second impedance elements have an impedance that suppresses a signal with a frequency twice the oscillating frequency at both the terminals of the first capacitor.

For example, the first and the second impedance elements are inductors.

Preferably, the inductor is a bonding wire.

For example, the first and the second impedance elements are a LC parallel resonant circuit including an inductor and a capacitor. The resonant frequency of the LC parallel resonant circuit is a frequency twice the oscillating frequency. When the first and the second impedance elements are a LC parallel resonant circuit, the size of the inductor can be further reduced.

Preferably, the voltage controlled oscillator further includes a second capacitor, one end of which is connected a base of the bipolar transistor as the first current source and a base of the bipolar transistor as the second current source, and the other end of which is grounded.

Thus, the thermal noise can be short-circuited, so that a voltage controlled oscillator having better noise characteristics can be provided.

Preferably, the bipolar transistors constituting the first and the second current sources have a collector made of a n-type semiconductor, a base made of a p-type semiconductor and an emitter made of an n-type semiconductor, and the collector is formed inside the emitter.

Thus, the parasitic capacitance between the collector and the p-type substrate can be reduced, so that even if the oscillating frequency is high, the current source transistor side becomes a high impedance as desired.

Preferably, the first and the second oscillating transistors are field-effect transistors in which a drain electrode encloses a source electrode.

Thus, the parasitic capacitance between the source and the p-type substrate can be reduced, so that even if the oscillating frequency is high, a desired negative resistance occurs.

A second aspect of the present invention is directed to a phase locked loop (PLL) circuit for outputting a local oscillating signal, including a voltage controlled oscillator for changing an oscillating frequency in accordance a control signal and outputting the local oscillating signal, a feedback portion for feeding back the local oscillating frequency signal that is output from the voltage controlled oscillator, a phase comparator for generating the control signal in accordance with a phase difference between an input reference signal and a feedback signal that is output from the feedback portion; and a loop filter for extracting a low frequency component of the control signal generated by the phase comparator and inputting the component to the voltage controlled oscillator. The voltage controlled oscillator comprises a parallel resonant circuit, a negative resistance circuit connected in parallel to the parallel resonant circuit, a first capacitor connected in parallel to the negative resistance circuit, a first current source connected between one terminal of the first capacitor and the negative resistance circuit, and a second current source connected between the other terminal of the first capacitor and the negative resistance circuit. The capacitance value of the first capacitor is a value that suppresses a signal with a frequency twice the oscillating frequency at both the terminals of the first capacitor, and each of the first and the second current sources is constituted by a bipolar transistor.

Thus, a PLL circuit that outputs a local oscillating signal with a stable oscillating frequency can be provided.

A third aspect of the present invention is directed to wireless communication equipment for transmitting and receiving wireless signals, including a phase locked loop (PLL) circuit for outputting a local oscillating signal and a transmitting and receiving circuit for transmitting and receiving the wireless signals, using the local oscillating signal that is output from the PLL circuit. The PLL circuit comprises a voltage controlled oscillator for changing an oscillating frequency in accordance a control signal and outputting the local oscillating signal, a feedback portion for feeding back the local oscillating frequency signal that is output from the voltage controlled oscillator, a phase comparator for generating the control signal in accordance with a phase difference between an input reference signal and a feedback signal that is output from the feedback portion and a loop filter for extracting a low frequency component of the control signal generated by the phase comparator and inputting the component to the voltage controlled oscillator. The voltage controlled oscillator includes a parallel resonant circuit, a negative resistance circuit connected in parallel to the parallel resonant circuit, a first capacitor connected in parallel to the negative resistance circuit, a first current source connected between one terminal of the first capacitor and the negative resistance circuit, and a second current source connected between the other terminal of the first capacitor and the negative resistance circuit. The capacitance value of the first capacitor is a value that suppresses a signal with a frequency twice the oscillating frequency at both the terminals of the first capacitor, and each of the first and the second current sources is constituted by a bipolar transistor.

Thus, wireless communication equipment that can transmit and receive wireless signals based on a local oscillating signal having a stable oscillating frequency can be provided.

According to the present invention, a voltage controlled oscillator with small phase noise due to 1/f noise, low cost and reduced fluctuations of the oscillating frequency can be provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing the configuration of a voltage controlled oscillator 1 of a first embodiment of the present invention;

FIG. 2 is a circuit diagram showing the configuration of a current mirror circuit including current source transistors 110 and 111;

FIG. 3A is a diagram showing an example of a layout in which a conventional voltage controlled oscillator 900 shown in FIG. 22 is formed on a chip;

FIG. 3B is a diagram showing an example of a layout in which a voltage controlled oscillator 1 shown in FIG. 1 is formed on a chip;

FIG. 4 is a circuit diagram of a voltage controlled oscillator in which a bypass capacitor 114 is connected;

FIG. 5 is a circuit diagram showing the configuration of a voltage controlled oscillator 2 of a second embodiment of the present invention;

FIG. 6A is a diagram showing the configuration of a spiral inductor;

FIG. 6B is a diagram showing the configuration of an inductor that is realized by drawing out conductors;

FIG. 7 is a circuit diagram showing the configuration of a voltage controlled oscillator when a LC parallel resonant circuit is used;

FIG. 8 is a circuit diagram showing the configuration of a voltage controlled oscillator 3 of a third embodiment of the present invention;

FIG. 9 is a diagram showing the configuration in which inductors 132 and 133 are realized with bonding wires;

FIG. 10 is a circuit diagram of a voltage controlled oscillator when a LC resonant circuit including an inductor and a capacitor is connected between the emitters of the current source transistors 110 and 111 and the ground;

FIG. 11 is a circuit diagram of a voltage controlled oscillator when a bypass capacitor (second capacitor) 114 is connected in parallel to the bases of the current source transistors 110 and 111 and is grounded;

FIG. 12A is a top view of an ordinary MOS transistor;

FIG. 12B is a cross-sectional view of an ordinary MOS transistor;

FIG. 13 is a cross-sectional view of an npn bipolar transistor that has a collector made of an n-type semiconductor, a base made of a p-type semiconductor and an emitter made of an n-type semiconductor and in which the emitter is formed inside the collector;

FIG. 14A is a top view of a MOS transistor having a ring structure;

FIG. 14B is a cross-sectional perspective view showing the internal structure of the MOS transistor having a ring structure shown in FIG. 14A;

FIG. 15 is a cross-sectional view of an npn bipolar transistor that has a collector made of an n-type semiconductor, a base made of a p-type semiconductor and an emitter made of an n-type semiconductor and in which the collector is formed inside the emitter, as the current source transistors 110 and 111;

FIG. 16 is a block diagram of a PLL circuit in a fifth embodiment of the present invention;

FIG. 17 is a block diagram of wireless communication equipment in a sixth embodiment of the present invention;

FIG. 18A is a graph showing the simulation results for illustrating the effect of an example of the voltage controlled oscillator of the present invention;

FIG. 18B is a graph showing the simulation results for illustrating the effect of an example of the voltage controlled oscillator of the present invention;

FIG. 19 is a circuit diagram showing the configuration of the conventional voltage controlled oscillator 900;

FIG. 20A is a schematic diagram showing the temporal change of the voltages at both terminals O1 and O2 of the resonant circuit in the conventional voltage controlled oscillator 900 shown in FIG. 19;

FIG. 20B is a schematic diagram showing the temporal change of the voltage at the source terminal P0 of the oscillating transistors 915 and 916 in the conventional voltage controlled oscillator 900 shown in FIG. 19;

FIG. 21 is a diagram showing the phase noise characteristics of the conventional voltage controlled oscillator 900 shown in FIG. 19;

FIG. 22 is a circuit diagram showing the configuration of the conventional voltage controlled oscillator 990 disclosed in the non-patent document 1;

FIG. 23A is a schematic diagram showing the temporal change of the voltages at both terminals O1 and O2 of the resonant circuit in the conventional voltage controlled oscillator 990 shown in FIG. 22;

FIG. 23B is a schematic diagram showing the temporal change of the voltage at the source terminal P1 of the oscillating transistor 915 in the conventional voltage controlled oscillator 990 shown in FIG. 22;

FIG. 23C is a schematic diagram showing the temporal change of the voltage at the source terminal P2 of the oscillating transistor 916 in the conventional voltage controlled oscillator 990 shown in FIG. 22; and

FIG. 24 is a diagram showing the phase noise characteristics of the voltage controlled oscillator 990 shown in FIG. 22.

### DESCRIPTION OF THE PREFERRED EMBODIMENTS

### First Embodiment

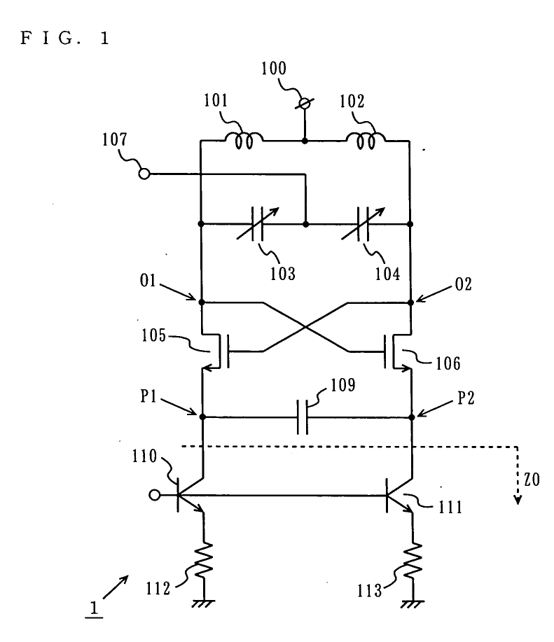

FIG. 1 is a circuit diagram showing the configuration of a voltage controlled oscillator 1 of a first embodiment of the present invention. In FIG. 1, the voltage controlled oscillator 1 includes a power terminal 100, inductors 101 and 102, variable capacitive elements 103 and 104, oscillating transistors 105 and 106, a frequency control terminal 107, a coupling capacitor 109, current source transistors 110 and 111, and resistors 112 and 113. In FIG. 1, a bias circuit and the like are omitted.

The variable capacitive elements 103 and 104 utilize the gate capacitance of variable capacitive diodes or field-effect transistors (FET). The oscillating transistors 105 and 106 are field-effect transistors (hereinafter, referred to as “FET”). The coupling capacitor 109 is a capacitor having a predetermined capacitance value. The current source transistor 110 and 111 are bipolar transistors.

The inductors 101 and 102 are connected in series. The power terminal 100 is connected between the inductors 101 and 102. The variable capacitive elements 103 and 104 are connected in series. The frequency control terminal 107 is connected between the variable capacitive elements 103 and 104. The series circuit including the inductors 101 and 102 and the series circuit including the variable capacitive elements 103 and 104 are connected in parallel so as to constitute a parallel resonant circuit.

The gate of the oscillating transistor 105 and the drain of the oscillating transistor 106 are connected to one end of the variable capacitive element 104. The gate of the oscillating transistor 106 and the drain of the oscillating transistor 105 are connected to one end of the variable capacitive element 103. The coupling capacitor 109 is connected between the source of the oscillating transistor 105 and the source of the oscillating transistor 106.

The collector of the current source transistor 110 is connected between the source of the oscillating transistor 105 and the coupling capacitor 109. The collector of the current source transistor 111 is connected between the oscillating transistor 106 and the coupling capacitor 109.

The base of the current source transistor 110 is connected to the base of the current source transistor 111. The emitter of the current source transistor 110 is grounded via the resistor 112. The emitter of the current source transistor 111 is grounded via the resistor 113.

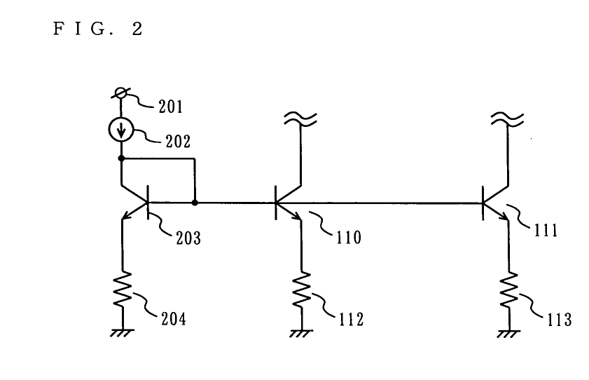

A circuit for constituting a current mirror circuit is connected to the base of the current source transistor 110 and the base of the current source transistor 111. FIG. 2 is a circuit diagram showing the configuration of a current mirror circuit including the current source transistors 110 and 111.

In FIG. 2, the current mirror circuit includes a power terminal 201, a constant current power 202, a bipolar transistor 203, a resistor 204, the current source transistors 110 and 111, and the resistors 112 and 113.

The collector of the bipolar transistor 203 is connected to the power terminal 201 via the constant current source 202. The collector and the base of the bipolar transistor 203 are connected to each other. The base of the bipolar transistor 203 is connected to the base of the current source transistors 110 and 111. The emitter of the bipolar transistor is grounded via the resistor 204.

The constant current source 202 generates a reference current Iref. A current having a constant current value constantly flows from the collectors to the emitters of the current source transistors 110 and 111 in accordance with the current value of the reference current Iref, the size ratio of the bipolar transistor 203 and the current source transistors 110 and 111 and the size ratio of the resistor 204 and the resistors 112 and 113. Therefore, the current source transistors 110 and 111 are constant current sources.

The capacitance values of the variable capacitive elements 103 and 104 are adjusted in accordance with the control voltage applied to the frequency control terminal 107. Thus, the resonant frequency of a parallel resonant circuit is changed. Therefore, the oscillating frequency can be controlled by controlling the control voltage. The oscillating transistors 105 and 106 are negative resistance circuits. A negative resistance is generated by the oscillating transistors 105 and 106, and a loss due to a parasitic resistance component of a resonant circuit is cancelled, and the oscillation conditions are satisfied.

The impedance (denoted by Z0 in FIG. 1) as seen from the source terminals P1 and P2 of the oscillating transistors 105 and 106 to the current source transistors 110 and 111 is:
Z0=ΔV/ΔI,
where ΔV is a voltage fluctuation of the source terminal P1 or P2, and ΔI is a current fluctuation thereof.

The current source transistors 110 and 111 operate so as to keep a constant current value with respect to the voltage fluctuation ΔV. Therefore, the current fluctuation ΔI is 0 with respect to the voltage fluctuation ΔV. Therefore, the impedance Z0 is high with respect to the voltage fluctuation of oscillating signals, that is, the oscillating frequency.

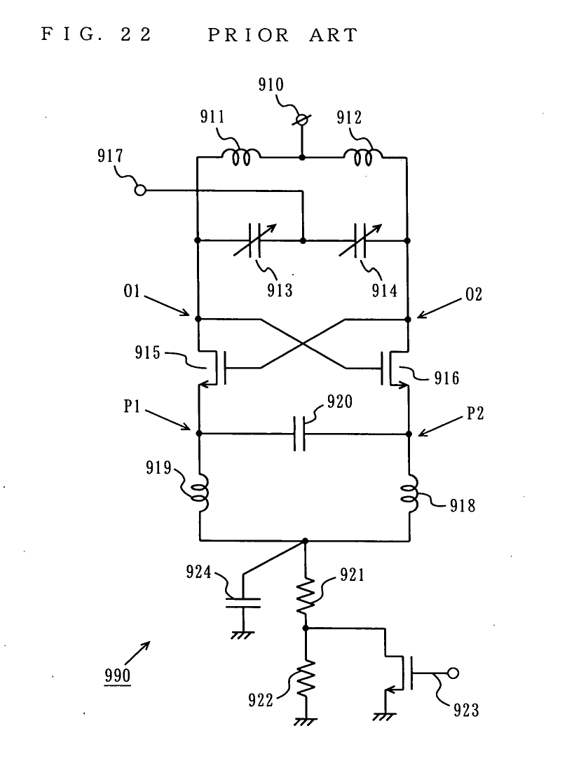

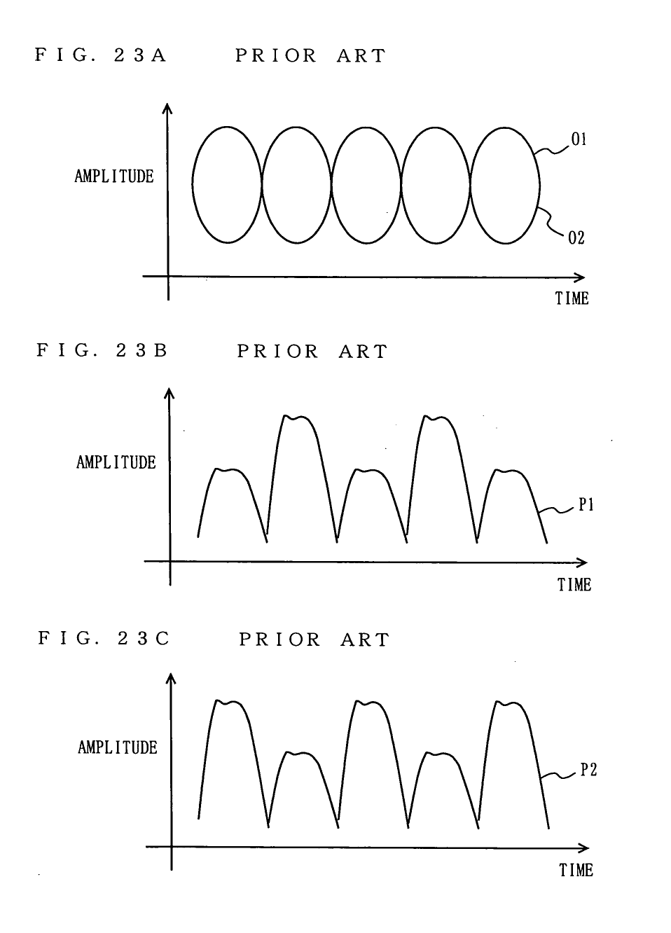

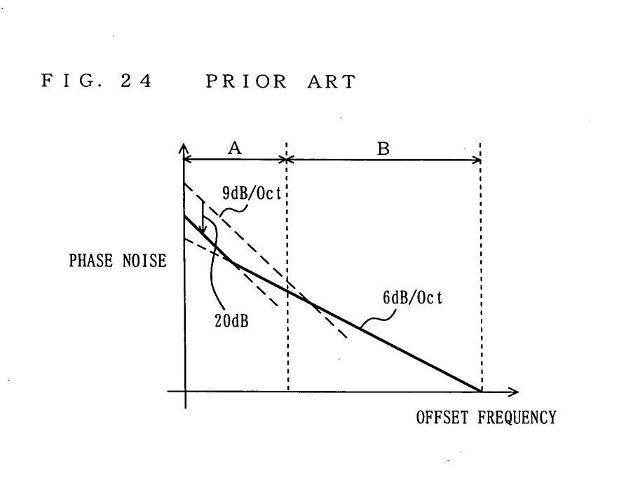

If the capacitance of the coupling capacitor 109 is set as appropriate, the terminals P1 and P2 are separated, and in the voltage fluctuations generated in the terminals P1 and P2, the 2 fo component can be reduced, as shown in FIGS. 23B and 23C.

The capacitance value of the coupling capacitor 109 can be obtained in the following manner. First, the capacitance of the coupling capacitor 109 is set to an appropriate value that provides a high impedance with respect to the oscillating frequency. Next, the capacitance value of the coupling capacitor 109 is decreased, and the capacitance value that does not satisfy the oscillation conditions is obtained. Next, the capacitance value of the coupling capacitor 109 is a little increased, and the smallest capacitance value that satisfies the oscillation conditions is obtained. This obtained capacitance value is an optimal capacitance value of the coupling capacitor 109. The temporal waveforms of the voltages at the terminals P1 and P2 when this capacitive value is selected are those shown in FIGS. 23B and 23C. In the waveforms shown in FIGS. 23B and 23C, the second harmonic having a frequency of 2 fo is suppressed. The capacitance value of the coupling capacitor 109 has to be a value that suppresses a signal with a frequency of 2 fo, which is twice the oscillating frequency fo, at both the terminals P1 and P2 of the coupling capacitor 109.

Therefore, the signal with a frequency of 2 fo is suppressed, so that the 1/f noise is suppressed from being converted to a frequency in the vicinity of the oscillating frequency by the interaction between the 1/f noise generated in the oscillating transistors 105 and 106 and the second harmonic. Thus, the phase noise can be suppressed.

In the present invention, since bipolar transistors in which the 1/f noise is small are used for the current source transistors 110 and 111, deterioration of the characteristics of phase noise caused by the current source transistors can be reduced.

Thus, in the first embodiment, the capacitance value of the coupling capacitor (first capacitor) is set to an appropriate value that provides a low impedance with respect to the oscillating frequency and a high impedance with respect to the 1/f noise so that a signal with a frequency of 2fo is suppressed at both the terminals of the coupling capacitor. Furthermore, current source transistors constituted by bipolar transistors are connected so that the ground side has a high impedance with respect to the oscillating frequency. Thus, the second harmonic can be suppressed, so that the 1/f noise is suppressed from being converted to a frequency in the vicinity of the oscillating frequency by the interaction between the 1/f noise generated in the oscillating transistors and the second harmonic. Thus, a voltage controlled oscillator with reduced phase noise can be provided.

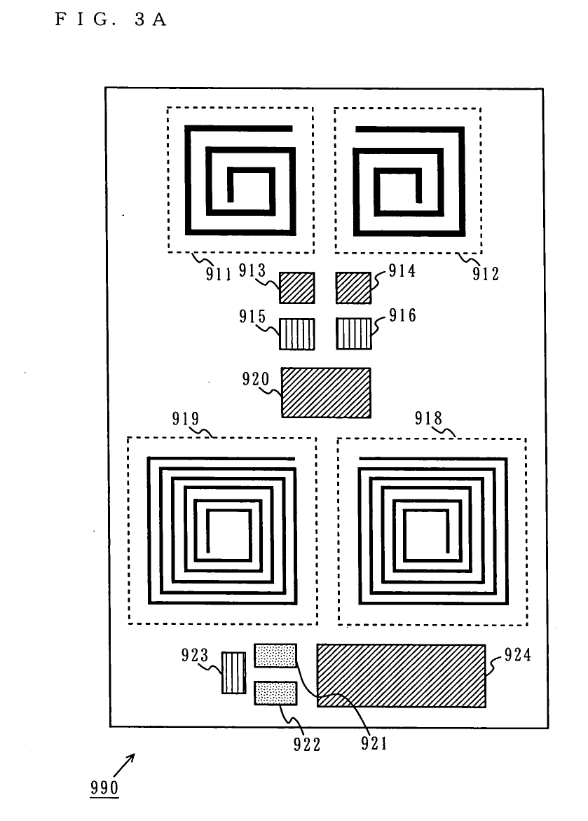

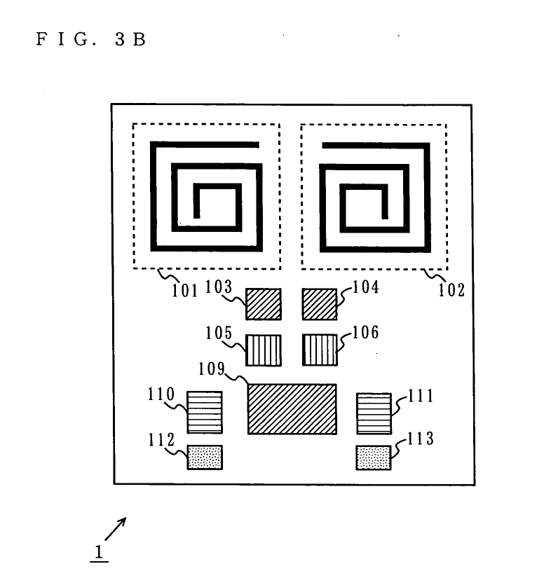

Furthermore, the configuration in which the current sources using bipolar transistors allow the ground side to have a high impedance with respect to the oscillating frequency is adopted. Therefore, compared with a conventional case where a high impedance with respect to the oscillating frequency is generated by using two inductors occupying large areas, the chip area can be reduced significantly, and thus the cost of a voltage controlled oscillator can be reduced. FIGS. 3A and 3B are diagrams for illustrating that the chip area is reduced significantly. FIG. 3A is a diagram showing an example of a layout in which the conventional voltage controlled oscillator 900 shown in FIG. 22 is formed on a chip. In FIG. 3A, the portions having the same function as in the conventional voltage controlled oscillator 900 shown in FIG. 22 bear the same reference numerals. FIG. 3B is a diagram showing an example of a layout in which a voltage controlled oscillator 1 shown in FIG. 1 is formed on a chip. In FIG. 3B, the portions having the same function as in the voltage controlled oscillator 1 shown in FIG. 1 bear the same reference numerals. As seen from a comparison of FIGS. 3A and 3B, in the voltage controlled oscillator 1 shown in FIG. 1, the two inductors 919 and 918 occupying large areas are eliminated, so that the chip area can be reduced significantly.

Furthermore, bipolar transistors are used as the constant current sources, so that the 1/f noise can be suppressed, compared with the case where FETs are used as the current sources, so that the phase noise can be further suppressed.

Furthermore, transistors are used as the constant current sources, so that fluctuations of the frequency due to the variation of the power voltage can be suppressed, compared with a conventional case where the constant current source is constituted by resistors.

A bypass capacitor may be connected in parallel between the base terminal of the current source transistor 110 and the base terminal of the current source transistor 111. FIG. 4 is a circuit diagram of a voltage controlled oscillator in which a bypass capacitor 114 is connected. The thermal noise generated in the bipolar transistor is mostly made up of the thermal noise generated by the base resistance. Therefore, the bypass capacitor 114 is connected between the base terminals in parallel, as shown in FIG. 4, so that the thermal noise generated in the bipolar transistor can be short-circuited, and the thermal noise can be prevented from flowing into the oscillating transistor side. Thus, the thermal noise can be reduced without reducing the impedance Z0, and therefore the phase noise characteristics of the voltage controlled oscillator can be further improved.

In this embodiment, the first and the second current sources are constituted by the current source transistors 110 and 111, respectively. However, each of the first and the second current sources may be constituted by two or more bipolar transistors. Also in the case where each of the first and the second current sources is constituted by two or more bipolar transistors, one bipolar transistor likewise serves as the current source.

### Second Embodiment

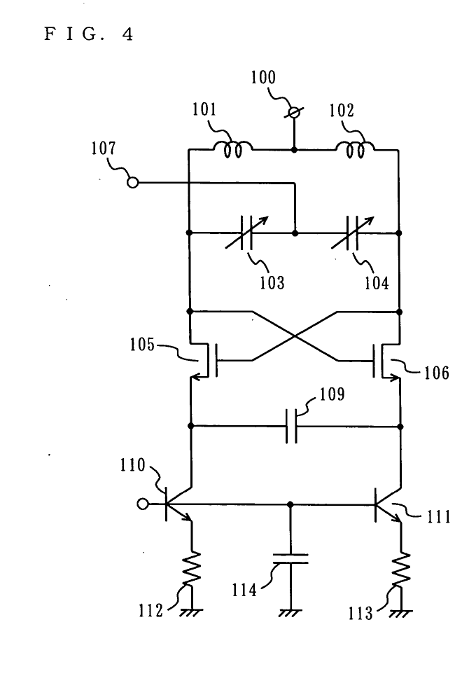

FIG. 5 is a circuit diagram showing the configuration of a voltage controlled oscillator 2 of a second embodiment of the present invention. In FIG. 5, the voltage controlled oscillator 2 includes a power terminal 100, inductors 101 and 102, variable capacitive elements 103 and 104, oscillating transistors 105 and 106, a frequency control terminal 107, a coupling capacitor 109, current source transistors 110 and 111, resistors 112 and 113, and inductors 120 and 121. In FIG. 5, a bias circuit and the like are omitted. In FIG. 5, the same portions as in the first embodiment bear the same reference numerals and are not described further.

In the first embodiment, the parasitic capacitance between the emitters and the collectors of the current source transistors 110 and 111 reduces the impedance Z0 as seen from the terminals P1 and P2 to the current source side with respect to higher oscillating frequencies. For example, in the case where the oscillating frequency is 5 GHz, this parasitic capacitance causes the impedance Z0 in the first embodiment to be a low impedance with respect to 10 GHz. Therefore, when the oscillating frequency is increased, in the first embodiment, a signal with a frequency twice the oscillating frequency cannot be suppressed at both the terminals of the coupling capacitor 109. Therefore, the effect of suppressing the phase noise cannot be obtained.

In the second embodiment, by inserting the inductors 120 and 121 having an impedance that suppresses a signal with a frequency twice the oscillating frequency at both the terminals of the coupling capacitor 109, the effect of suppressing the phase noise also can be obtained with respect to higher frequencies.

Such an impedance is obtained in the following manner. First, an appropriate inductor that provides a high impedance with respect to a frequency twice the oscillating frequency is connected, and the temporal change of the voltage at the terminals P1 and P2 is simulated. Then, the impedance values of the inductors 120 and 121 are changed so that an optimal impedance with which the signal with a frequency twice the oscillating frequency is suppressed is obtained. Thus, the impedances of the inductors 120 and 121 are obtained.

Thus, by connecting the inductors 120 and 121 having a large impedance at 2 fo, good phase noise characteristics can be realized even if the oscillating frequency is high.

Furthermore, the impedance ZL of an inductor is expressed by ZL=2 πfL, where L is an inductance, and f is a frequency, and is proportional to the frequency. Therefore, as the frequency is increased, the inductance can be reduced. In this embodiment, since it is sufficient that the inductors 120 and 121 provide a high impedance with respect to the frequency twice the oscillating frequency, the inductors 120 and 121 can be smaller than the inductors 918 and 919 used in the conventional configuration shown in FIG. 22. The chip area of the inductors 120 and 121 is ½ or less of the chip area of the inductors 918 and 919 used in the conventional configuration shown in FIG. 22 for the following reason. When two spiral inductors are simply connected in series, the inductance becomes twice. Furthermore, when an inductor is configured so as to be wound around the outer circumference of a spiral inductor, the inductance becomes twice or more by the function of the mutual inductance. Therefore, in the case where it is sufficient to provide a high impedance with respect to the frequency twice the oscillating frequency, it is sufficient that the inductance L is ½, so that the chip area of the inductor becomes ½ or less.

Thus, in the second embodiment, an inductor having a large impedance with respect to the second harmonic is provided, so that even if the oscillating frequency is high, the impedance Z0 can be kept high. Therefore, even if the oscillating frequency is high, good noise characteristics can be realized.

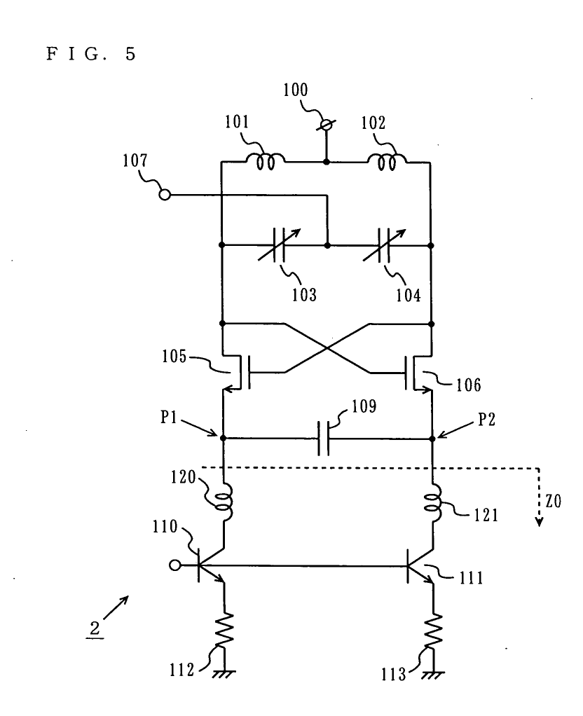

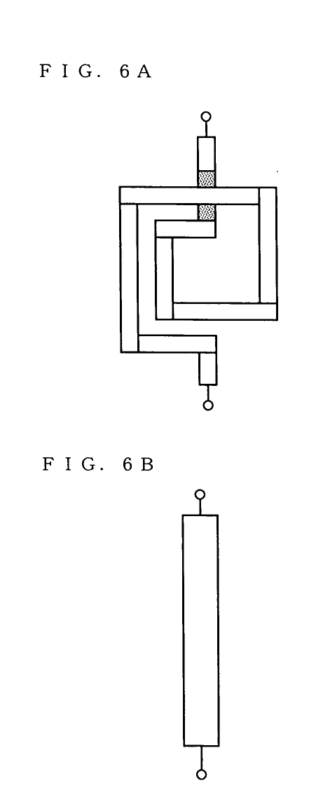

The inductors 120 and 121 can be realized with spiral inductors. FIG. 6A is a diagram showing the configuration of a spiral inductor. When the oscillating frequency is high, the inductors 120 and 121 can be realized by drawing out conductors. FIG. 6B is a diagram showing the configuration of an inductor that is realized by drawing out conductors.

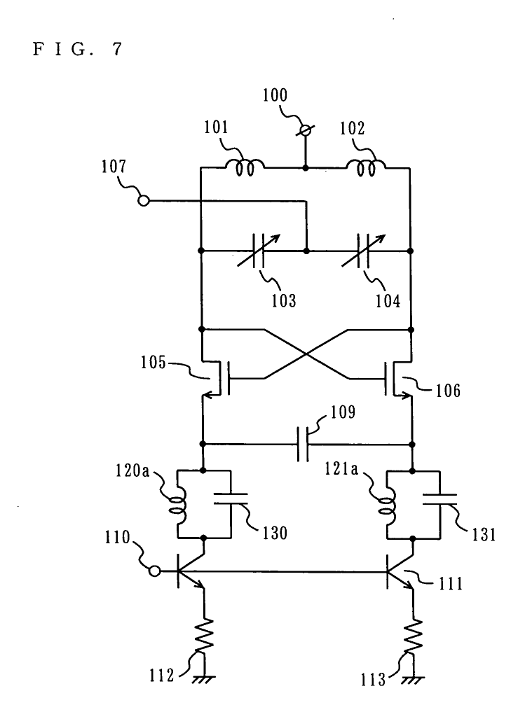

In place of the inductors 120 and 121, a LC parallel resonant circuit including an inductor and a capacitor can be used. FIG. 7 is a circuit diagram showing the configuration of a voltage controlled oscillator when a LC parallel resonant circuit is used. As shown in FIG. 7, in place of the inductors 120 and 121, a LC parallel resonant circuit including an inductor 120a and a capacitor 130 and a LC parallel resonant circuit including an inductor 121a and a capacitor 131 are connected to the collector side of the current source transistors 110 and 111.

The impedance of the entire LC resonant circuit is a value that suppresses the signal with a frequency twice the oscillating frequency at both the terminals of the coupling capacitor 109, as described above.

Herein, when the inductance of the inductor is taken as L, and the capacitance of the capacitor is taken as C,

$$L = \frac{1}{{C ( 4 π fo )}^{2}} is given , based on 2 fo = \frac{1}{2 π \sqrt{LC}} .$$

Therefore, according to the configuration in which the LC parallel resonant circuit is used, when the oscillating frequency is high, the inductance L is further reduced. Thus, even if the oscillating frequency is high, the chip area can be reduced significantly.

In the second embodiment, an inductor or a LC resonant circuit is used as an element connected between the current source transistors 110 and 111 and the coupling capacitor. However, the element is not limited thereto, as long as it is a first and second impedance element having a desired impedance.

Also in the second embodiment, as shown in FIG. 4, a bypass capacitor (second capacitor) is connected to the bases of the current source transistors 110 and 111 in parallel and is grounded, so that the influence due to thermal noise can be suppressed.

### Third Embodiment

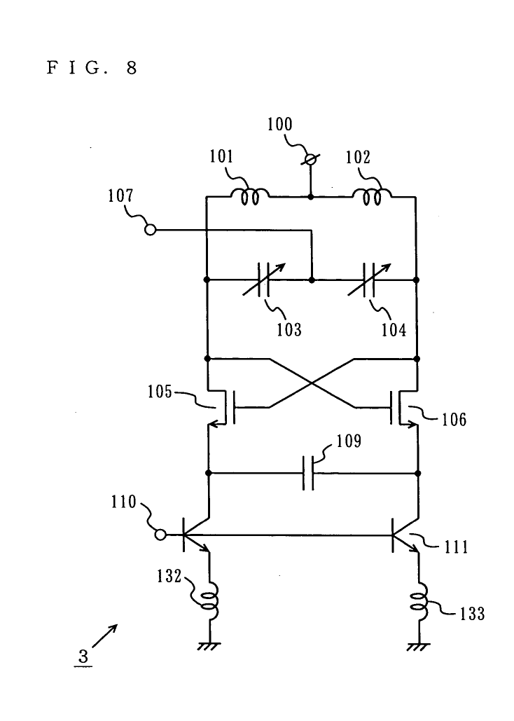

FIG. 8 is a circuit diagram showing the configuration of a voltage controlled oscillator 3 of a third embodiment of the present invention. In FIG. 8, the voltage controlled oscillator 3 includes a power terminal 100, inductors 101 and 102, variable capacitive elements 103 and 104, oscillating transistors 105 and 106, a frequency control terminal 107, a coupling capacitor 109, current source transistors 110 and 111, and inductors 132 and 133. In FIG. 8, a bias circuit and the like are omitted. In FIG. 8, the same portions as in the first embodiment bear the same reference numerals and are not described further.

The inductors 132 and 133 are connected between the emitters of the current source transistors 110 and 111 and the ground. The inductors 132 and 133 have an impedance that suppresses a signal with a frequency twice the oscillating frequency at both the terminals of the coupling capacitor 109 similarly to the inductors 120 and 121 in the second embodiment.

Similarly to the second embodiment, by connecting the inductors 132 and 133 having a large impedance at 2 fo, even if the oscillating frequency is high, good phase noise characteristics can be realized.

Furthermore, similarly to the second embodiment, the impedance of the inductor is proportional to the frequency. Therefore, as the frequency is increased, the inductance can be reduced. In this embodiment, since it is sufficient that the inductors 132 and 133 provide a high impedance with respect to the frequency twice the oscillating frequency, the inductors 132 and 133 can be smaller than the inductors 918 and 919 used in the conventional configuration shown in FIG. 22. The chip area of the inductors 132 and 133 is about ½ or less of the chip area of the inductors 918 and 919 used in the conventional configuration shown in FIG. 22.

Thus, in the third embodiment, an inductor having a large impedance with respect to the second harmonic is provided, so that even if the oscillating frequency is high, the impedance in a current source portion can be kept high. Therefore, even if the oscillating frequency is high, good noise characteristics can be realized.

The inductors 132 and 133 can be realized with the spiral inductors or conductors shown in FIGS. 6A and 6B.

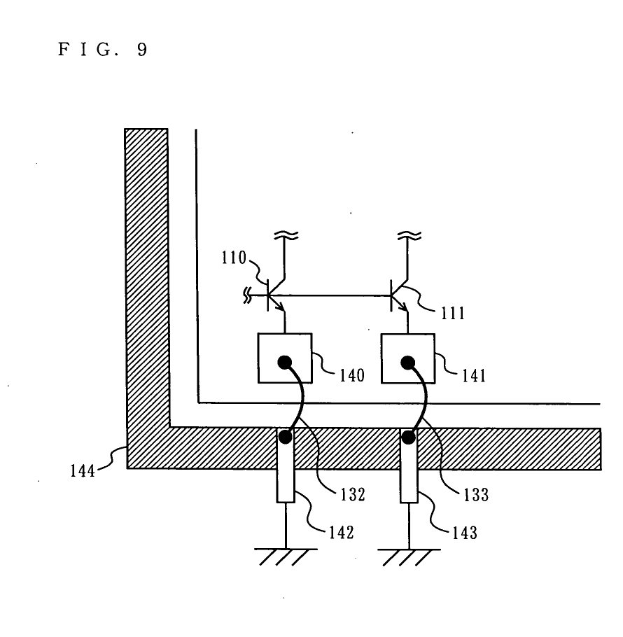

Furthermore, the inductors 132 and 133 can be realized with bonding wires. FIG. 9 is a diagram showing the configuration in which inductors 132 and 133 are realized with bonding wires. In FIG. 9, the voltage controlled oscillator 3 is formed inside a package supporting member 144. In FIG. 9, circuit portions other than the current source transistors 110 and 111 are omitted. The terminals on one side of the inductors 132 and 133 are connected to the emitters of the current source transistors 110 and 111 via pads 140 and 141. The terminals on the other side of the inductors 132 and 133 are grounded via lead pins 142 and 143.

Thus, by realizing the inductors with wires, the circuit shown in FIG. 8 can be realized without increasing the chip area, so that the cost can be suppressed.

In the case where inductance is not sufficient with bonding wires, chip inductors may be connected to the lead pins 142 and 143 so as to supplement insufficient inductance.

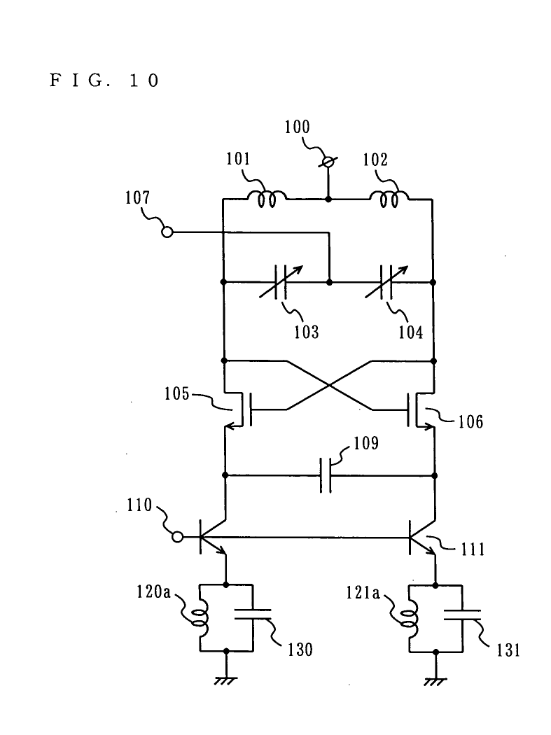

In place of the inductors 132 and 133, as shown in FIG. 7, a LC parallel resonant circuit including an inductor and a capacitor is connected to the emitter of the current source transistors 110 and 111 and the ground. FIG. 10 is a circuit diagram of a voltage controlled oscillator when a LC resonant circuit including an inductor and a capacitor is connected between the emitters of current source transistors 110 and 111 and the ground.

In the third embodiment, an inductor or a LC resonant circuit is used as the element connected between the current source transistors 110 and 111 and the ground. However, the element is not limited thereto, as long as it is a first and second impedance element having a desired impedance.

Also in the third embodiment, as shown in FIG. 4, a bypass capacitor (second capacitor) is connected in parallel to the bases of the current source transistors 110 and 111 and is grounded, so that the influence due to thermal noise can be suppressed. FIG. 11 is a circuit diagram of a voltage controlled oscillator when a bypass capacitor (second capacitor) 114 is connected in parallel to the bases of the current source transistors 110 and 111 and is grounded.

### Fourth Embodiment

In a fourth embodiment of the present invention, a voltage controlled oscillator that can provide a desired effect even with a high oscillating frequency will be described. In general, when configuring the circuit shown in FIG. 1, a MOS transistor in which a drain electrode and a source electrode are arranged in parallel, and a gate electrode is arranged between the drain electrode and the source electrode (hereinafter, referred to as “ordinary MOS transistor”) is used as the oscillating transistors 105 and 106. An npn bipolar transistor that has a collector made of an n-type semiconductor, a base made of a p-type semiconductor and an emitter made of an n-type semiconductor and in which the emitter is formed inside the collector is used as the current source transistors 110 and 111.

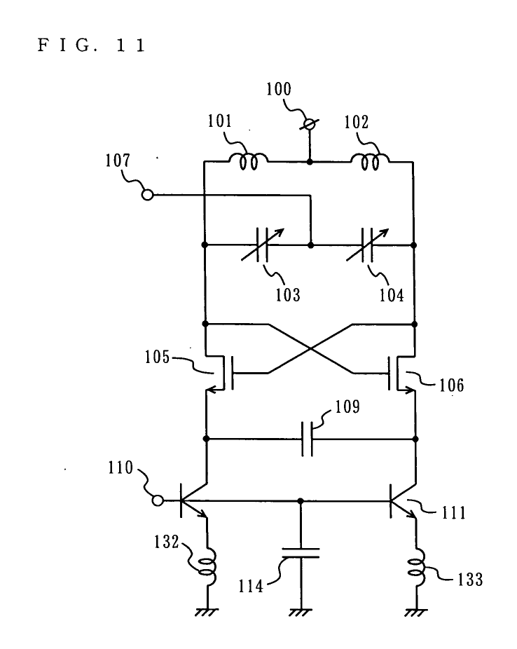

FIG. 12A is a top view of an ordinary MOS transistor. FIG. 12B is a cross-sectional view of an ordinary MOS transistor. As shown in FIGS. 12A and 12B, an ordinary MOS transistor has a gate electrode 301 between a drain electrode 300 and a source electrode 302. In a p-type substrate 311, n-type semiconductors 308 and 309, and a channel 310 between the n-type semiconductors 308 and 309 are formed. The drain electrode 300 is formed on the n-type semiconductor 308. A drain terminal 303 is connected to the drain electrode 300. A gate oxide film 307 is formed on the channel 310. The gate electrode 301 is formed on the gate oxide film 307. A gate terminal 304 is connected to the gate electrode 301. The source electrode 302 is formed on the n-type semiconductor 309. A source terminal 305 is connected to the source electrode 302. In this manner, an ordinary MOS transistor is formed.

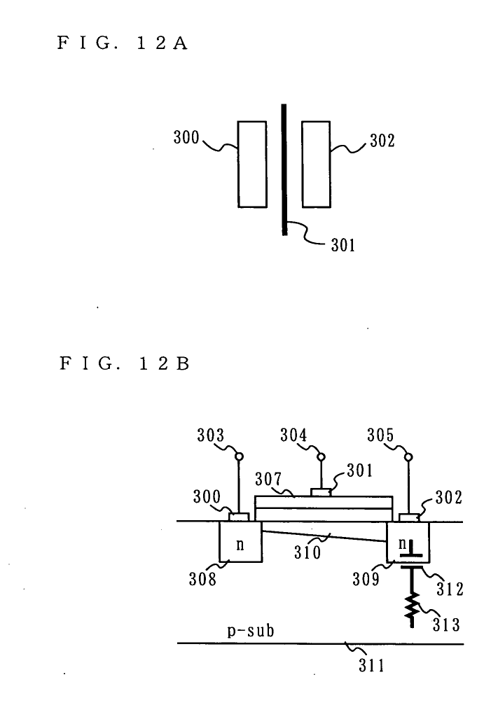

FIG. 13 is a cross-sectional view of an npn bipolar transistor that has a collector made of an n-type semiconductor, a base made of a p-type semiconductor and an emitter made of an n-type semiconductor and in which the emitter is formed inside the collector. In FIG. 13, the npn bipolar transistor includes a p-type substrate 326, an n-type semiconductor 325 formed in the p-type substrate 326, a p-type semiconductor 323 formed in the n-type semiconductor 325, and an n-type semiconductor 324 formed in the p-type semiconductor 323. A collector electrode 329a is formed on the n-type semiconductor 325. A collector terminal 322 is connected to the collector electrode 329a. A base electrode 329b is formed on the p-type semiconductor 323. A base terminal 321 is connected to the base electrode 329b. An emitter electrode 329c is formed on the n-type semiconductor 324. An emitter terminal 320 is connected to the emitter electrode 329c. In this manner, an npn bipolar transistor is formed that has a collector made of an n-type semiconductor, a base made of a p-type semiconductor and an emitter made of an n-type semiconductor and in which the emitter is formed inside the collector.

A significant influence of a parasitic capacitance 312 and a parasitic resistance 313 present between the n-type semiconductor 309 and the p-type substrate 311 on the source terminal 305 side appears, as the oscillating frequency is increased. The influence of the parasitic capacitance 312 and the parasitic resistance 313 prevents a desired high impedance from being obtained on the source side with high oscillating frequencies.

Furthermore, a significant influence of a parasitic capacitance 327 and a parasitic resistance 328 present between the n-type semiconductor 325 and the p-type substrate 326 on the collector terminal 322 side appears, as the oscillating frequency is increased. The influence of the parasitic capacitance 327 and the parasitic resistance 328 prevents a desired high impedance from being obtained on the current source transistors 110 and 111 side with high oscillating frequencies.

Therefore, in the fourth embodiment, a MOS transistor having a ring structure is used as the oscillating transistors 105 and 106, and an npn bipolar transistor that has a collector made of an n-type semiconductor, a base made of a p-type semiconductor and an emitter made of an n-type semiconductor and in which the collector is formed inside the emitter is used as the current source transistors 110 and 111. It should be noted that only the oscillating transistors 105 and 106 may be constituted by the MOS transistors having a ring structure, or that only the current source transistors 110 and 111 may be constituted by the npn bipolar transistor in which the collector is formed inside the emitter.

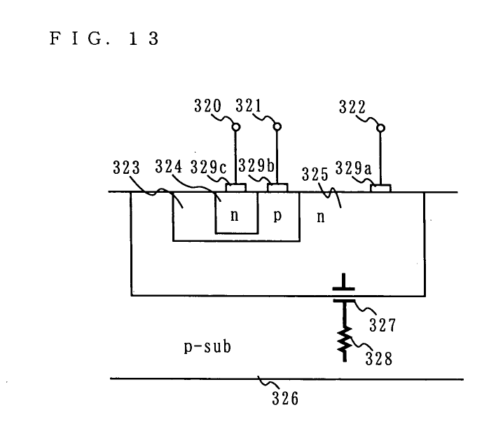

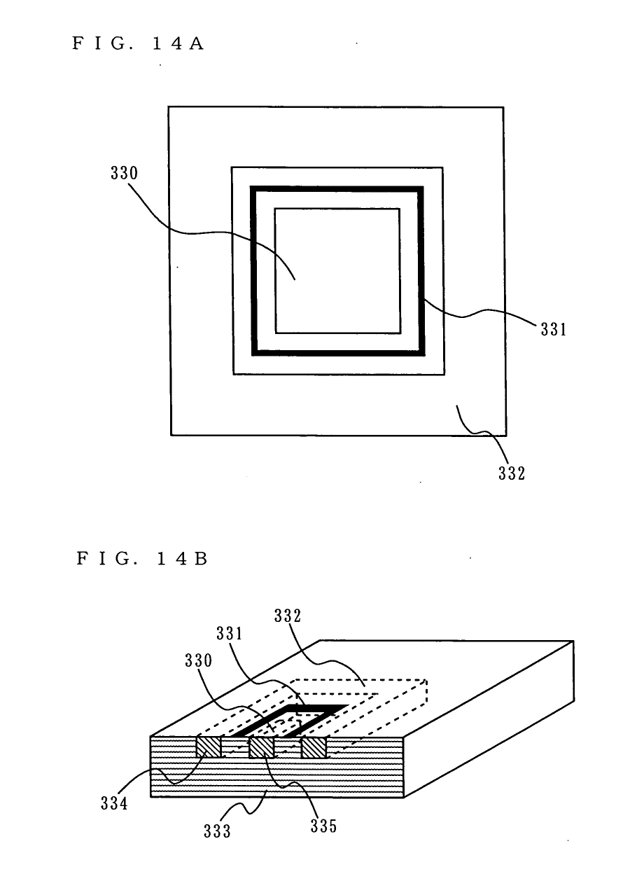

FIG. 14A is a top view of a MOS transistor having a ring structure. FIG. 14B is a cross-sectional perspective view showing the internal structure of the MOS transistor having a ring structure shown in FIG. 14A. As shown in FIGS. 14A and 14B, the MOS transistor having a ring structure includes a p-type substrate 333, an n-type semiconductor 334 that is formed in a ring shape in the p-type substrate 333, and an n-type semiconductor 335 that is formed so as to be enclosed by the n-type semiconductor 334 in a ring shape. A source electrode 330 is formed on the n-type semiconductor 335. Agate electrode 331 is formed so as to enclose the source electrode 330. A drain electrode 332 is formed so as to enclose the gate electrode 331. In the MOS transistor having such a ring structure, the source area is smaller than that of the ordinary MOS transistor. Therefore, the parasitic capacitance between the source and the p-type substrate is smaller than that of the ordinary MOS transistor. Thus, the problem that the influence of the parasitic capacitance prevents a desired high impedance from being obtained with high oscillating frequencies can be solved.

FIG. 15 is a cross-sectional view of an npn bipolar transistor that has a collector made of an n-type semiconductor, a base made of a p-type semiconductor and an emitter made of an n-type semiconductor and in which the collector is formed inside the emitter as the current source transistors 110 and 111. In FIG. 15, the same portions as in the npn bipolar transistor in FIG. 13 bear the same reference numerals. The npn bipolar transistor shown in FIG. 15 is different from the npn bipolar transistor shown in FIG. 13 in that the collector and the emitter are arranged the other way around. That is to say, in the npn bipolar transistor shown in FIG. 15, the n-type semiconductor 324 in which the collector is formed is formed inside the n-type semiconductor 325 in which the emitter is formed. In the npn bipolar transistor shown in FIG. 15, the parasitic capacitance between the n-type semiconductor 324 in which the collector is formed and the p-type substrate 326 is smaller than the parasitic capacitance 327 between the n-type semiconductor 325 in which the collector is formed and the p-type substrate 326 in the npn bipolar transistor shown in FIG. 13. Therefore, a desired high impedance can be obtained on the current source transistors 110 and 111 side with high oscillating frequencies.

### Fifth Embodiment

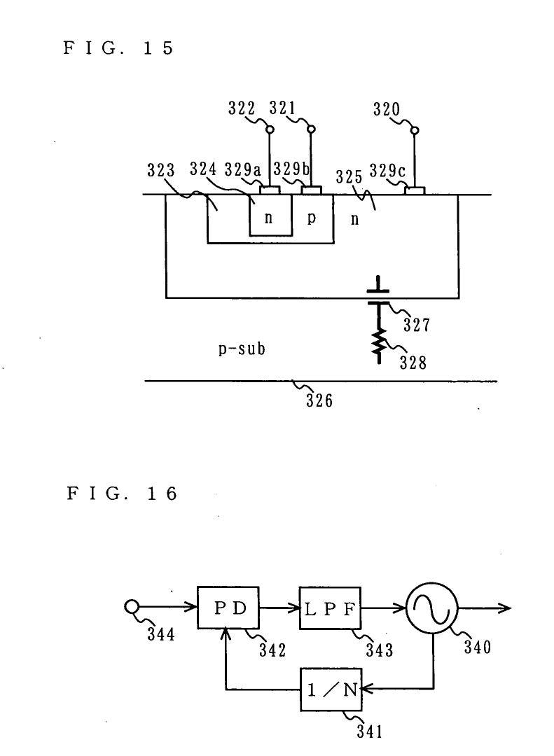

The voltage controlled oscillators that have been described in the first to the fourth embodiment may be used as a local oscillator in a PLL (phase locked loop) circuit. FIG. 16 is a block diagram of a PLL circuit in a fifth embodiment of the present invention. In FIG. 16, a PLL circuit 5 includes a voltage controlled oscillator 340 that is anyone of the first to the fourth embodiments, a frequency-divider 341, a phase comparator (PD) 342, a loop filter (LPF) 343, and a reference signal input terminal 344.

The voltage controlled oscillator 340 changes the oscillating frequency in accordance with the input control signal and outputs it as a local oscillating signal. The frequency-divider 341 is a feedback portion that divides the local oscillating signal that is output from the voltage controlled oscillator 340, and feeds it back to the phase comparator 342 as a feedback signal. A reference signal is input to the reference signal input terminal 344. The reference signal input to the reference signal input terminal 344 is input to the phase comparator 342. The phase comparator 342 generates a control signal in accordance with the phase difference between the reference signal and the feedback signal and outputs the control signal. The loop filter 343 extracts a low frequency component of the control signal that is output from the phase comparator 342, and inputs it to the voltage controlled oscillator 340. Thus, the PLL circuit 5 can output stable local oscillating signals by synthesizing the local oscillating signals with the phase of the reference signal.

The frequency-divider 341 may be a feedback portion that feeds the local oscillating signal that is output from the voltage controlled oscillator 340 as a feedback signal back to the phase comparator 342 directly without dividing the local oscillating signal.

### Sixth Embodiment

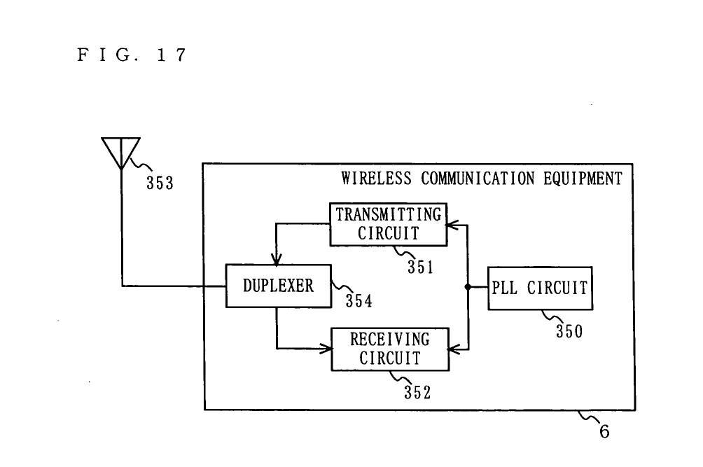

The voltage controlled oscillator that have been described in the first to the fourth embodiment may be used as a local oscillator in wireless communication equipment. FIG. 17 is a block diagram of wireless communication equipment in a sixth embodiment of the present invention. In FIG. 17, wireless communication equipment 6 includes a PLL circuit 350, a transmitting circuit 351, a receiving circuit 352, a duplexer 354, and an antenna 353.

The PLL circuit 350 has the same configuration as that of the PLL circuit 5 shown in the fifth embodiment and outputs local oscillating signals. The transmitting circuit 351 generates an up-converted transmitting signal based on the local oscillating signal that is output from the PLL circuit 350 and outputs it as a wireless signal via a duplexer 354 and an antenna 353. The receiving circuit 352 down-converts the wireless signal that is received via the antenna 353 and the duplexer 354, based on the local oscillating signal that is output from the PLL circuit 350 for signal-receiving processing. Thus, the wireless communication equipment 6 can transmit and receive wireless signals based on stable local oscillating signals.

If a transmitting and receiving circuit that can transmit and receive wireless signals is provided, the configuration of the wireless communication circuit 6 is not limited to the configuration shown in FIG. 17.

### EXAMPLE

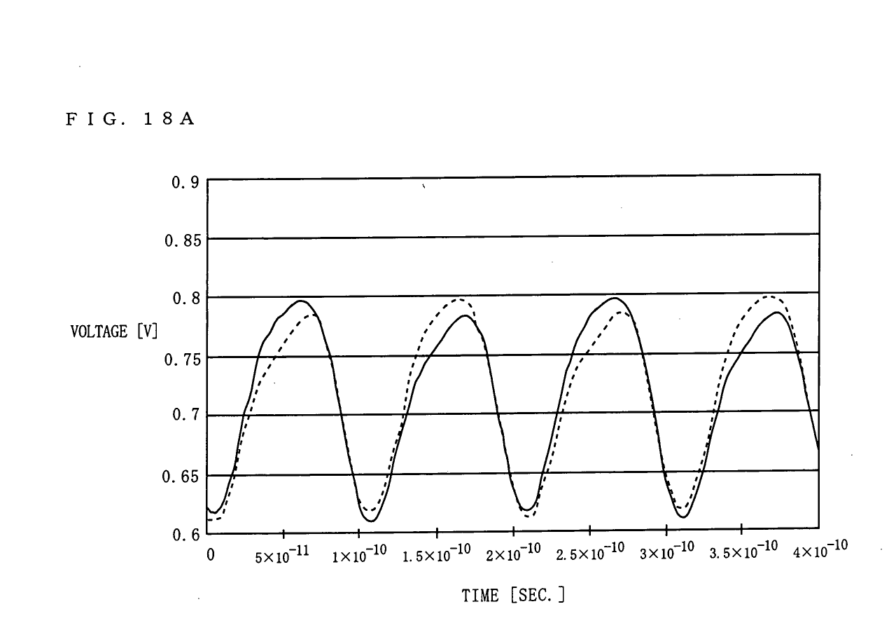

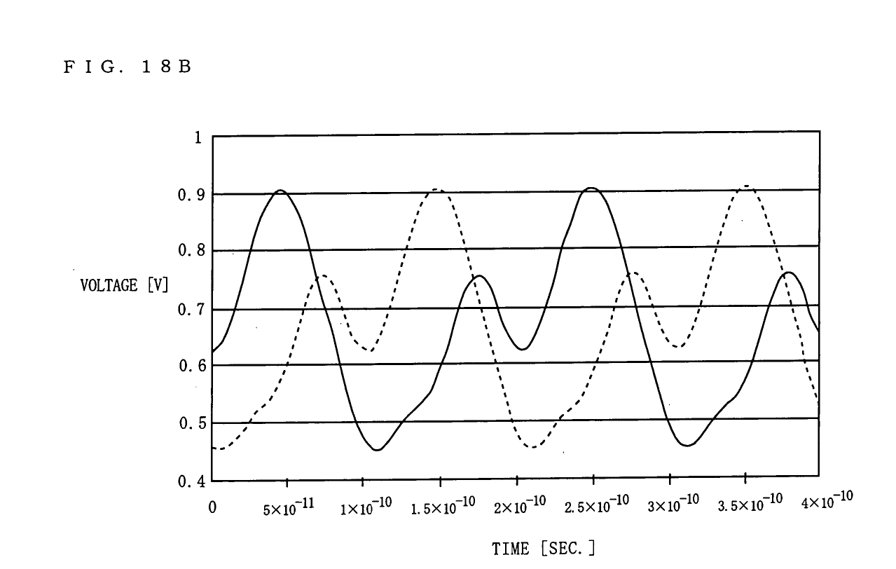

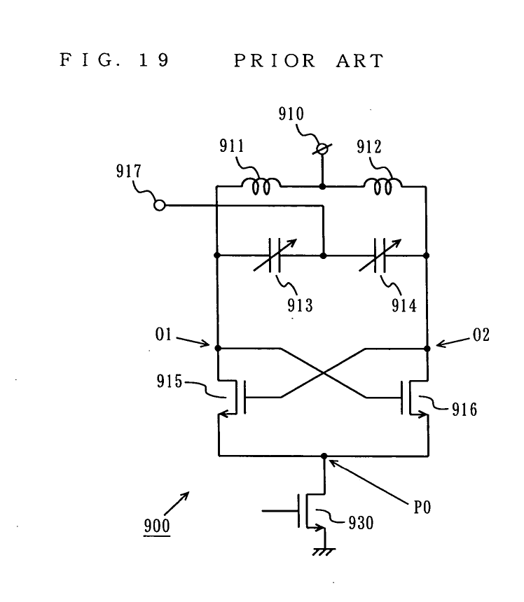

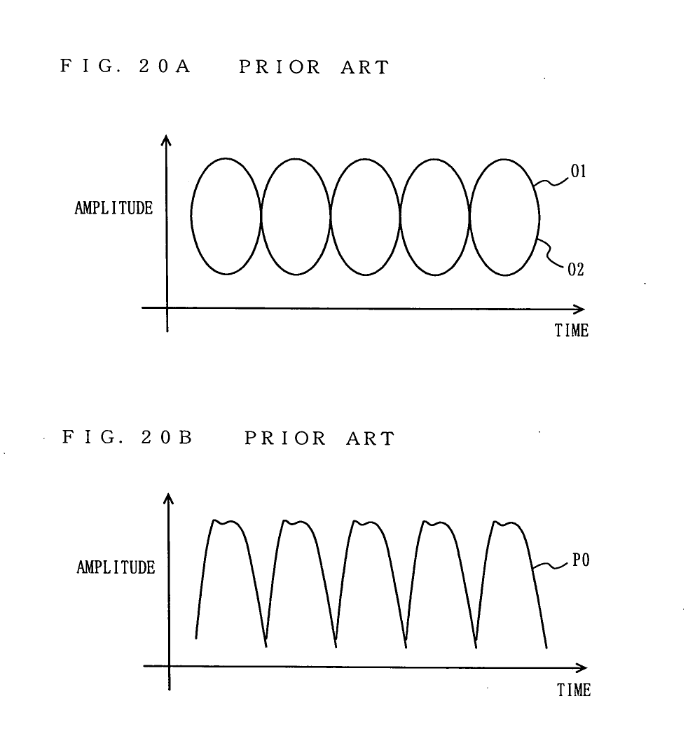

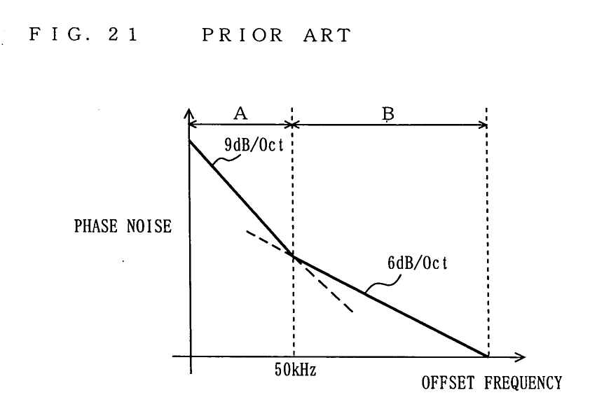

FIGS. 18A and 18B are graphs showing the simulation results for illustrating the effect of an example of the voltage controlled oscillator of the present invention. In FIG. 18A, the temporal change of the voltage in the source terminal P1 of the oscillating transistor 105 when the capacitance of the coupling capacitor 109 of the voltage controlled oscillator shown in FIG. 1 is assumed to be 4 pF, and the oscillating frequency fo is assumed to be 5 GHz is shown by a solid line, and the temporal change of the voltage in the source terminal P2 of the oscillating transistor 106 is shown by a dotted line. In FIG. 18B, the temporal change of the voltage in the source terminal P1 of the oscillating transistor 105 when the capacitance of the coupling capacitor 109 of the voltage controlled oscillator shown in FIG. 1 is assumed to be 0.5 pF, and the oscillating frequency fo is assumed to be 5 GHz is shown by a solid line, and the temporal change of the voltage in the source terminal P2 of the oscillating transistor 106 is shown by a dotted line. In FIG. 18A, the horizontal axis shows time, and one scale is 5×10⁻¹¹ (sec). The vertical axis shows voltages, and one scale is 0.05 (V). In FIG. 18B, the horizontal axis shows time, and one scale is 5×10⁻¹¹ (sec). The vertical axis shows voltages, and one scale is 0.1 (V).

In the example shown in FIG. 18A, the voltage changes in a cycle of 10⁻¹⁰ (sec). Therefore, it can be said that the voltage changes at a frequency of 10 GHz, which is twice the oscillating frequency of 5 GHz, and the second harmonic cannot be suppressed. On the other hand, in the example shown in FIG. 18B, no voltage change is observed in a cycle of 10⁻¹⁰ (sec) (10 GHz) Therefore, in the example shown in FIG. 18B, the second harmonic can be suppressed. Thus, the inventors of the present invention configured the circuit shown in FIG. 1 in the voltage controlled oscillator having a frequency fo of 5 GHz and set the capacitance value of the coupling capacitor 109 to 0.5 pF, which is a value that can suppress a signal with a frequency twice the oscillating frequency, and thus confirmed in simulations that a voltage controlled oscillator in which 1/f noise is suppressed from being converted to a frequency in the vicinity of the oscillating frequency by the interaction between the 1/f noise of the oscillating transistor and the second harmonic can be provided.

The voltage controlled oscillator of the present invention has small phase noise, a low cost and reduced fluctuations of the oscillating frequency, and can be applied to a semiconductor integrated circuit, a PLL circuit, wireless communication equipment or the like.

While the invention has been described in detail, the foregoing description is in all aspects illustrative and not restrictive. It is understood that numerous other modifications and variations can be devised without departing from the scope of the invention.

1. A voltage controlled oscillator for changing an oscillating frequency in accordance an input control voltage, comprising:
a parallel resonant circuit;
a negative resistance circuit connected in parallel to the parallel resonant circuit;
a first capacitor connected in parallel to the negative resistance circuit;
a first current source connected between one terminal of the first capacitor and the negative resistance circuit, and
a second current source connected between the other terminal of the first capacitor and the negative resistance circuit,
wherein a capacitance value of the first capacitor is a value that suppresses a signal with a frequency twice the oscillating frequency at both the terminals of the first capacitor, and
each of the first and the second current sources is constituted by a bipolar transistor.

2. The voltage controlled oscillator according to the claim 1, wherein the negative resistance circuit comprises:
a first oscillating transistor constituted by an field-effect transistor; and
a second oscillating transistor constituted by an field-effect transistor, and
the parallel resonant circuit is connected between drains of the first and the second oscillating transistors,
the first capacitor is connected between sources of the first and the second oscillating transistors,
a gate of the first oscillating transistor is connected to a drain of the second oscillating transistor,
a gate of the second oscillating transistor is connected to a drain of the first oscillating transistor,
a collector of the bipolar transistor as the first current source is connected between the first capacitor and a source of the first oscillating transistor, and
a collector of the bipolar transistor as the second current source is connected between the first capacitor and a source of the second oscillating transistor.

3. The voltage controlled oscillator according to claim 2, further comprising:
a first impedance element connected between the collector of the bipolar transistor as the first current source and the first capacitor; and
a second impedance element connected between the collector of the bipolar transistor as the second current source and the first capacitor,
wherein the first and the second impedance elements have an impedance that suppresses a signal with a frequency twice the oscillating frequency at both the terminals of the first capacitor.

4. The voltage controlled oscillator according to claim 3, wherein the first and the second impedance elements are inductors.

5. The voltage controlled oscillator according to claim 3,
wherein the first and the second impedance elements are a LC parallel resonant circuit including an inductor and a capacitor, and
a resonant frequency of the LC parallel resonant circuit is a frequency twice the oscillating frequency.

6. The voltage controlled oscillator according to claim 2, further comprising:
a first impedance element connected between an emitter of the bipolar transistor as the first current source and the ground; and
a second impedance element connected between an emitter of the bipolar transistor as the second current source and the ground,
wherein the first and the second impedance elements have an impedance that suppresses a signal with a frequency twice the oscillating frequency at both the terminals of the first capacitor.

7. The voltage controlled oscillator according to claim 6, wherein the first and the second impedance elements are inductors.

8. The voltage controlled oscillator according to claim 7, wherein the inductor is a bonding wire.

9. The voltage controlled oscillator according to claim 6,
wherein the first and the second impedance elements are a LC parallel resonant circuit including an inductor and a capacitor, and
a resonant frequency of the LC parallel resonant circuit is a frequency twice the oscillating frequency.

10. The voltage controlled oscillator according to claim 2, further comprising a second capacitor, one end of which is connected a base of the bipolar transistor as the first current source and a base of the bipolar transistor as the second current source, and the other end of which is grounded.

11. The voltage controlled oscillator according to claim 1, wherein the bipolar transistors constituting the first and the second current sources have a collector made of a n-type semiconductor, a base made of a p-type semiconductor and an emitter made of an n-type semiconductor, and
the collector is formed inside the emitter.

12. The voltage controlled oscillator according to claim 2, wherein the first and the second oscillating transistors are field-effect transistors in which a drain electrode encloses a source electrode.

13. A phase locked loop (PLL) circuit for outputting a local oscillating signal, comprising:
a voltage controlled oscillator for changing an oscillating frequency in accordance a control signal and outputting the local oscillating signal;
a feedback portion for feeding back the local oscillating frequency signal that is output from the voltage controlled oscillator;
a phase comparator for generating the control signal in accordance with a phase difference between an input reference signal and a feedback signal that is output from the feedback portion; and
a loop filter for extracting a low frequency component of the control signal generated by the phase comparator and inputting the component to the voltage controlled oscillator,
wherein the voltage controlled oscillator comprises:
a parallel resonant circuit;
a negative resistance circuit connected in parallel to the parallel resonant circuit;
a first capacitor connected in parallel to the negative resistance circuit;
a first current source connected between one terminal of the first capacitor and the negative resistance circuit; and
a second current source connected between the other terminal of the first capacitor and the negative resistance circuit,
wherein a capacitance value of the first capacitor is a value that suppresses a signal with a frequency twice the oscillating frequency at both the terminals of the first capacitor, and
each of the first and the second current sources is constituted by a bipolar transistor.

14. A wireless communication equipment for transmitting and receiving wireless signals, comprising:
a phase locked loop (PLL) circuit for outputting a local oscillating signal and
a transmitting and receiving circuit for transmitting and receiving the wireless signals, using the local oscillating signal that is output from the PLL circuit,
wherein the PLL circuit comprises:
a voltage controlled oscillator for changing an oscillating frequency in accordance a control signal and outputting the local oscillating signal;
a feedback portion for feeding back the local oscillating frequency signal that is output from the voltage controlled oscillator;
a phase comparator for generating the control signal in accordance with a phase difference between an input reference signal and a feedback signal that is output from the feedback portion; and
a loop filter for extracting a low frequency component of the control signal generated by the phase comparator and inputting the component to the voltage controlled oscillator,
wherein the voltage controlled oscillator comprises:
a parallel resonant circuit;
a negative resistance circuit connected in parallel to the parallel resonant circuit;
a first capacitor connected in parallel to the negative resistance circuit;
a first current source connected between one terminal of the first capacitor and the negative resistance circuit; and
a second current source connected between the other terminal of the first capacitor and the negative resistance circuit,
wherein a capacitance value of the first capacitor is a value that suppresses a signal with a frequency twice the oscillating frequency at both the terminals of the first capacitor, and
each of the first and the second current sources is constituted by a bipolar transistor.
